(19) United States
(12) Patent Application Publication
(10) Pub. No.: US 2023/0217631 A1
(43) Pub. Date: Jul. 6, 2023

(54) VAPOR CHAMBER

(71) Applicant: Murata Manufacturing Co., Ltd., Nagaokakyo-shi (JP)

(72) Inventors: Keijiro KOJIMA, Nagaokakyo-shi (JP); Nobuhito TSUBAKI, Nagaokakyo-shi (JP)

(21) Appl. No.: 18/182,725

(22) Filed: Mar. 13, 2023

Related U.S. Application Data
(63) Continuation of application No. PCT/JP2021/032412, filed on Sep. 3, 2021.

(30) Foreign Application Priority Data
Sep. 18, 2020 (JP) 2020-157487

(51) Int. Cl. H05K 7/20

(52) U.S. Cl. CPC H05K 7/20336

(57) ABSTRACT

A vapor chamber that includes: a housing with an internal space between a first sheet and a second sheet; a working fluid in the internal space; a plurality of first projecting portions on an inner wall surface of the first sheet and spaced from each other; a plurality of second projecting portions on an inner wall surface of the first sheet and spaced from each other, an area of a section of each of the second projecting portions perpendicular to a height direction being larger than an area of a section of each of the first projecting portions perpendicular to the height direction; a plurality of pillars on an inner wall surface of the second sheet and spaced from each other and at respective positions overlapping the plurality of second projecting portions; and a wick between and joined to the plurality of pillars and the plurality of second projecting portions.

### CROSS REFERENCE TO RELATED APPLICATIONS

The present application is a continuation of International application No. PCT/JP2021/032412, filed Sep. 3, 2021, which claims priority to Japanese Patent Application No. 2020-157487, filed Sep. 18, 2020, the entire contents of each of which are incorporated herein by reference.

### FIELD OF THE INVENTION

The present invention relates to a vapor chamber.

### BACKGROUND OF THE INVENTION

In recent years, elements have been highly integrated and have been improved in performance, thus increasing the amount of heat generated. In addition, size reductions of products increase the heat generation densities thereof. Thus, measures to dissipate heat are important. This situation is particularly prominent in the field of mobile terminals such as smart phones and tablets. For example, a graphite sheet is often used as a member for countermeasures against heat. However, the amount of heat transported thereby is not sufficient. Thus, use of various members for countermeasures against heat have been examined. In particular, use of vapor chambers, which are planar heat pipes, have been examined because such vapor chambers are capable of diffusing heat significantly effectively.

Such a vapor chamber has a structure in which a working medium and a wick configured to transport the working medium by capillary force are enclosed in a housing. The working medium absorbs heat from a heat generation element in an evaporation portion configured to absorb heat from the heat generation element, evaporates in the vapor chamber, moves to a condensation portion, and is cooled to return to a liquid phase. The working medium that has returned to the liquid phase is moved to the evaporation portion closer to the heat generation element again by the capillary force of the wick and cools the heat generation element. By repeating this operation, the vapor chamber is capable of operating autonomously without external power and of diffusing heat two-dimensionally at high speed by using evaporation latent heat and condensation latent heat of the working medium.

To respond to thickness reductions of mobile terminals such as smart phones and tablets, vapor chambers are also required to be reduced in thickness. Such a thin vapor chamber is required to have both a sufficient mechanical strength and heat transportation efficiency.

Patent Document 1 discloses a vapor chamber using a housing in which pillars are provided between two sheets.

Projecting portions, a wick, and the pillars are stacked in the housing and are loosely joined to each other at the contact points therebetween by, for example, diffusion bonding. Such a configuration enables a thin structure to be increased in the maximum amount of heat transported.
Patent Document 1: International Publication No.

2018/199218

### SUMMARY OF THE INVENTION

When the vapor chamber is used at a temperature equal to or higher than the boiling point of a working fluid, the working fluid evaporates to cause the internal pressure of the housing of the vapor chamber to be easily increased. Such an increase in the internal pressure of the housing of the vapor chamber may cause the projecting portions and the wick to be disjointed to expand the vapor chamber.

This effect is most noticeable when a working fluid having a low boiling point is used to further improve the performance of the vapor chamber.

The present invention is made to solve the above problem, and an object of the present invention is to provide a vapor chamber capable of inhibiting the vapor chamber from being expanded when the internal pressure of a housing is increased. In addition, an object of the present invention is to provide an electronic device including the vapor chamber.

A vapor chamber of the present invention includes: a housing having a first sheet and a second sheet that have respective outer edges joined to each other such that the first sheet and the second sheet face each other and define an internal space between an inner wall surface of the first sheet and an inner wall surface of the second sheet; a working fluid enclosed in the internal space of the housing; a plurality of first projecting portions on the inner wall surface of the first sheet so as to be spaced from each other; a plurality of second projecting portions on the inner wall surface of the first sheet so as to be spaced from each other, an area of a section of each of the plurality of second projecting portions perpendicular to a height direction thereof being larger than an area of a section of each of the plurality of first projecting portions perpendicular to the height direction thereof; a plurality of pillars on the inner wall surface of the second sheet so as to be spaced from each other and at respective positions overlapping the plurality of second projecting portions in a plan view in a direction in which the first sheet and the second sheet face each other; and a wick between and joined to the plurality of pillars and the plurality of second projecting portions.

An electronic device of the present invention includes the vapor chamber of the present invention.

The present invention enables provision of the vapor chamber capable of inhibiting the vapor chamber from being expanded when the internal pressure of the housing is increased.

### BRIEF DESCRIPTION OF THE DRAWINGS

FIG. 1 is a schematic sectional view of an example of a structure of a vapor chamber.

FIG. 2 is a schematic top sectional view of an example of the vapor chamber.

FIG. 3 is a schematic top view of an example in which the position of a pillar and the position of a second projecting portion overlap each other.

FIG. 4 is a schematic top view of another example in which the position of the pillar and the position of the second projecting portion overlap each other.

FIG. 5 is a schematic top sectional view of an example of another structure of the vapor chamber.

FIG. 6 is a sectional view taken along line B-B in FIG. 5.

FIG. 7 includes photographs each illustrating an external appearance of a stripped plane of Comparative Example 1.

FIG. 8 includes photographs each illustrating an external appearance of a stripped plane of Example 1.

### DETAILED DESCRIPTION OF THE PREFERRED EMBODIMENTS

A vapor chamber of the present invention will be described below.

However, the present invention is not limited to the following configurations, and modifications can be applied thereto as appropriate without changing the gist of the present invention. Combinations of two or more different preferable configurations of the present invention described below are also included in the present invention.

It is needless to say that embodiments described below are examples, and configurations of different embodiments can be partially replaced or combined.

Figures described below are schematic, and, for example, the size and the aspect ratio thereof may differ from those of an actual product.

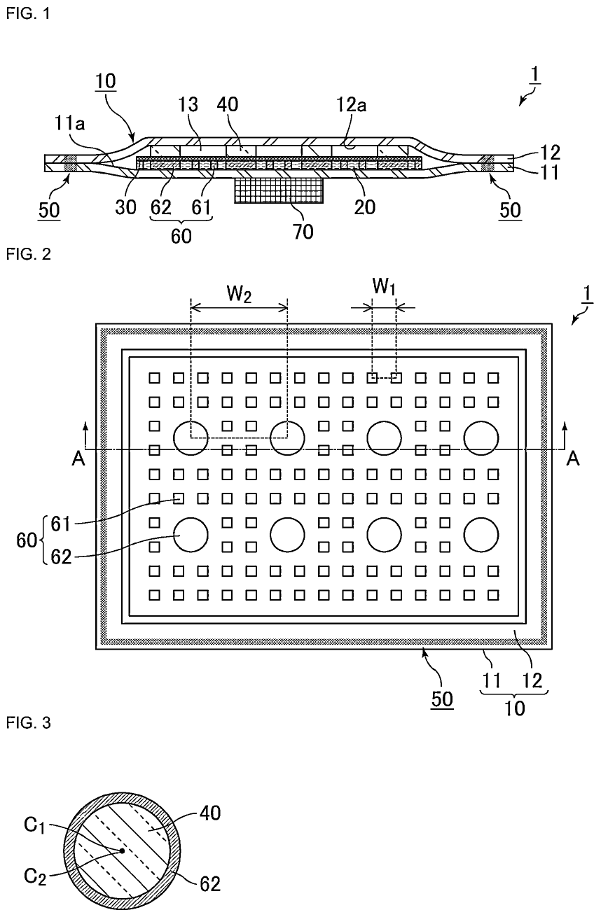

FIG. 1 is a schematic sectional view of an example of a structure of a vapor chamber.

A vapor chamber 1 illustrated in FIG. 1 includes a housing 10, which is formed by a first sheet 11 and a second sheet 12 facing each other and has an internal space 13 between an inner wall surface 11a of the first sheet 11 and an inner wall surface 12a of the second sheet 12, a working fluid 20, which is enclosed in the internal space 13 of the housing 10, a plurality of projecting portions 60, which are disposed on the inner wall surface 11a of the first sheet 11 so as to be spaced from each other, a plurality of pillars 40, which are disposed on the inner wall surface 12a of the second sheet 12 so as to be spaced from each other, and a wick 30, which is provided between the pillars 40 and the projecting portions 60. The wick 30 is disposed along a direction along the inner wall surface 11a of the first sheet 11 and the inner wall surface 12a of the second sheet 12.

The first sheet 11 and the second sheet 12 are joined to each other and are sealed with a sealing portion 50 at the outer edges thereof.

The projecting portions 60 may be integral with the first sheet 11 and may be formed by, for example, etching the inner wall surface 11a of the first sheet 11. Similarly, the pillars 40 may be integral with the second sheet 12 and may be formed by, for example, etching the inner wall surface 12a of the second sheet 12. In the present embodiment, the projecting portions 60 (first projecting portions 61 and second projecting portions 62) and the pillars 40 each have a pillar shape.

The working fluid 20 exists, in a liquid phase, in the wick 30 and the part of the internal space 13 between the projecting portions 60. In addition, the working fluid 20 exists, mainly in a gas phase (water vapor when the working fluid is water), in the part of the internal space 13 between the pillars 40.

For example, a heat generation member 70 is disposed on a main surface (outer wall surface) of the first sheet 11 that does not face the second sheet 12. Examples of such a heat generation member include an electronic component of an electronic device, such as a central processing unit (CPU).

Heat of the heat generation member 70 evaporates the working fluid 20 in the liquid phase immediately above the heat generation member 70 to take away the heat of the heat generation member 70, and the evaporated working fluid moves from the wick 30 to the part of the internal space 13 between the pillars 40.

The evaporated working fluid 20 moves in the housing 10 and condenses into the liquid phase in the vicinity of the outer edge of the housing 10.

The working fluid 20 in the liquid phase is absorbed by the wick 30 with the capillary force of the wick 30 and moves in the wick 30 toward the heat generation member 70 again to function to take away heat of the heat generation member 70.

The working fluid moves in the housing so as to circulate in this manner, thus cooling the heat generation member with the vapor chamber.

The heat generation member 70 may be disposed on a main surface (outer wall surface) of the second sheet 12 that does not face the first sheet 11.

FIG. 2 is a schematic top sectional view of an example of the vapor chamber.

FIG. 2 is a top view when viewed from the side where the second sheet 12, which forms the vapor chamber 1, is located and illustrates the disposition of the projecting portions 60 so as to be seen through the second sheet 12 and the wick 30.

It can also be said that FIG. 1 is a sectional view of the vapor chamber 1 taken along section A-A illustrated in FIG. 2.

The projecting portions 60 include a plurality of first projecting portions 61 and a plurality of second projecting portions 62 which are larger than the first projecting portions 61. In the present description, the projecting portions each refer to a part having a height relatively higher than that of the periphery thereof and include parts projecting from the inner wall surface of the first sheet and parts having a relatively higher height due to recessed portions (for example, grooves) formed in the inner wall surface. The size of each projecting portion is determined by the area of a section thereof perpendicular to the height direction.

In the vapor chamber of the present invention, the pillars are disposed at respective positions overlapping the second projecting portions in plan view in the direction in which the first sheet and the second sheet face each other.

The pillars are disposed at respective positions overlapping the second projecting portions each having a large area, thus firmly joining the pillars, the wick, and the second projecting portions. Accordingly, the joining strength between the projecting portions (second projecting portions) and the wick is increased. As a result, it is possible to inhibit the vapor chamber from being expanded when the internal pressure of the housing is increased.

Specifically, it is possible to inhibit the vapor chamber from being expanded even when the vapor chamber is used at a temperature higher than the boiling point of the working fluid. Thus, the vapor chamber is also suitable for a case in which a working fluid having a low boiling point is used.

In addition, in the vapor chamber of the present invention, the wick is joined to the pillars and the second projecting portions. The method for joining these parts is not particularly limited. Examples of such a joining method include laser welding, resistance welding, diffusion bonding, solder bonding, and brazing. In particular, it is preferable to join these parts by diffusion bonding. It is possible to firmly join these parts by diffusion bonding. Thus, it is possible to more reliably inhibit the vapor chamber from being expanded when the internal pressure of the housing is increased.

Preferable configurations of the pillar and the second projecting portion will be described.

FIG. 3 is a schematic top view of an example in which the position of the pillar and the position of the second projecting portion overlap each other.

This top view is a figure in plan view in the direction in which the first sheet and the second sheet face each other.

The pillar 40 is disposed at a position overlapping the second projecting portion 62 in this plan view. That is, the pillar 40 overlaps the second projecting portion 62 having a large sectional shape.

FIG. 3 illustrates the configuration in which the pillar 40 entirely overlaps the second projecting portion 62. That is, 100% of the area of the pillar overlaps the second projecting portion 62.

In the vapor chamber, the percentage of the area of the pillar overlapping the second projecting portion is not particularly limited. Preferably, 75% or more of the area of the pillar overlaps the second projecting portion.

75% of the area of the pillar overlaps the second projecting portion, thus firmly joining most of the pillar and the second projecting portion. Accordingly, the joining strength between the projecting portions and the wick is further increased.

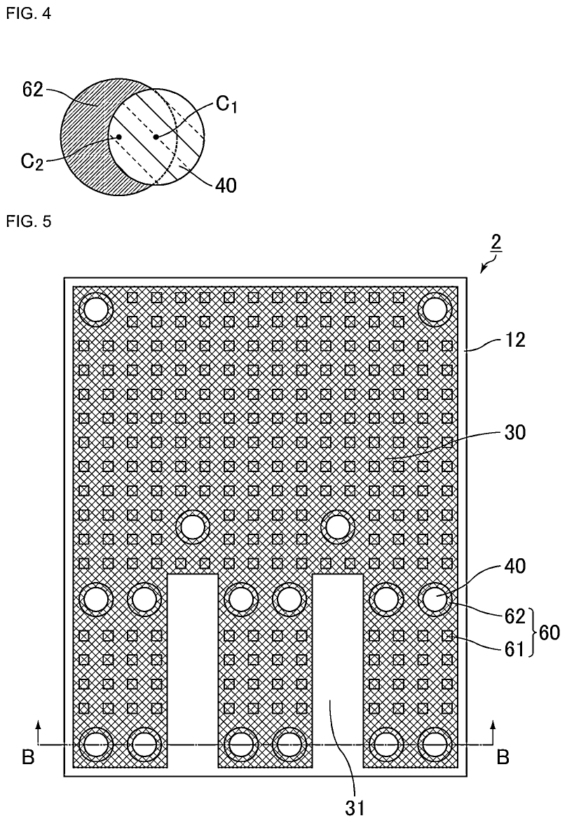

FIG. 4 is a schematic top view of another example in which the position of the pillar and the position of the second projecting portion overlap each other.

FIG. 3 illustrates an example in which the pillar 40 entirely overlaps the second projecting portion 62. However, FIG. 4 illustrates an example in which the pillar 40 partially overlaps the second projecting portion 62.

In the vapor chamber, preferably, the area of a section of the second projecting portion perpendicular to the height direction is larger than the area of a section of the pillar perpendicular to the height direction. In any of the example illustrated in FIG. 3 and the example illustrated in FIG. 4, the area of a section of the second projecting portion 62 perpendicular to the height direction is larger than the area of a section of the pillar 40 perpendicular to the height direction.

The area of a section of the second projecting portion perpendicular to the height direction is larger than the area of a section of the pillar perpendicular to the height direction. Thus, even when misalignment between the second projecting portion and the pillar occurs, the misalignment is easily allowed.

In addition, preferably, the ratio of the area of a section of the second projecting portion perpendicular to the height direction to the area of a section of the pillar perpendicular to the height direction is 100% to 130%.

The shape of a section of the pillar perpendicular to the height direction is not particularly limited and may be a circle or a polygon (a triangle, a quadrilateral (a rectangle or a square), a pentagon, or a hexagon).

The sectional shape of the pillar and the sectional shape of the second projecting portion may the same as each other or different from each other. Preferably, the sectional shape of the pillar and the sectional shape of the second projecting portion are similar shapes. In addition, the sectional shape of the pillar and the sectional shape of the second projecting portion may be the same (congruent).

FIGS. 3 and 4 each illustrate the shape of the pillar and the shape of the second projecting portion that are circles.

The pillars support the first sheet and the second sheet from the inside. The pillars are disposed in the housing, thus enabling the housing to be inhibited from being deformed, for example, when the pressure in the housing is reduced or when an external pressure from the outside of the housing is applied to the housing.

The disposition of the pillars is not particularly limited. Preferably, the pillars are evenly disposed. For example, the pillars are disposed in a lattice point pattern or a staggered pattern such that the intervals between the pillars adjacent to each other are regular. The pillars are evenly disposed, thus enabling the entire vapor chamber to have a uniform strength.

In addition, preferably, the interval between the pillars adjacent to each other is 1 mm to 5 mm. The manner in which the interval between the pillars adjacent to each other is determined can be similar to the manner in which the interval between the second projecting portions is determined described below.

In addition, preferably, the interval between the pillars is equal to the interval between the second projecting portions.

In addition, preferably, the pattern in which the pillars are disposed is the same as the pattern in which the second projecting portions are disposed.

In addition, preferably, the center of one of the figure forming the pillar and the figure forming the second projecting portion overlaps the other of the figure forming the pillar and the figure forming the second projecting portion in plan view in the direction in which the first sheet and the second sheet face each other. In addition, preferably, in plan view in the direction in which the first sheet and the second sheet face each other, the center of the figure forming the pillar is disposed at a position overlapping the second projecting portion, and the center of the figure forming the second projecting portion is disposed at a position overlapping the pillar. Furthermore, preferably, the center of the figure forming the pillar and the center of the figure forming the second projecting portion coincide with each other.

In FIG. 3, a center C₁ of the figure forming the pillar 40 and a center C₂ of the figure forming the second projecting portion 62 coincide with each other. In FIG. 4, the center C₁ of the figure forming the pillar 40 and the center C₂ of the figure forming the second projecting portion 62 do not coincide with each other. However, the center C₁ of the figure forming the pillar 40 overlaps the second projecting portion 62, and the center C₂ of the figure forming the second projecting portion 62 overlaps the pillar 40.

The centroid of the figure forming the pillar and the centroid of the figure forming the second projecting portion can be used as the respective centers of the figures.

Preferably, the area of a section of the second projecting portion perpendicular to the height direction is 0.2 mm² to 4 mm². In addition, preferably, the area of a section of the pillar perpendicular to the height direction is 0.15 mm² to 4 mm².

In addition, preferably, the pillar does not overlap the first projecting portion in plan view in the direction in which the first sheet and the second sheet face each other.

Next, preferable configurations of the first projecting portion and the second projecting portion will be described.

Preferably, the first projecting portion and the second projecting portion have the same height. In the present description, the height of each projecting portion is a height from a position of the inner wall surface of the first sheet 11 where the projecting portion is not provided.

The shape of each of a section of the first projecting portion perpendicular to the height direction and a section of the second projecting portion perpendicular to the height direction is not particularly limited and may be a circle or a polygon (a triangle, a quadrilateral (a rectangle or a square), a pentagon, or a hexagon).

The sectional shape of the first projecting portion and the sectional shape of the second projecting portion may be equal to each other or different from each other. FIG. 2 illustrates the sectional shape of the first projecting portion 61 that is a square and the sectional shape of the second projecting portion 62 that is a circle, the second projecting portion 62 being larger than the first projecting portion 61.

The area of a section of the second projecting portion perpendicular to the height direction is larger than the area of a section of the first projecting portion perpendicular to the height direction. In addition, preferably, the area of a section of the second projecting portion perpendicular to the height direction is 20 times to 200 times of the area of a section of the first projecting portion perpendicular to the height direction.

Preferably, the second projecting portion is somewhat large to achieve a sufficient joining strength between the second projecting portions and both the wick and the pillars. When the first projecting portion is also large, the space in which a working fluid flows is insufficient. Thus, preferably, the first projecting portion is somewhat small. In terms of this, the ratio of the area of the second projecting portion to the area of the first projecting portion can be determined.

Preferably, the area of a section of the first projecting portion perpendicular to the height direction is 0.0025 mm² to 0.04 mm².

Preferably, the interval between the second projecting portions is larger than the interval between the first projecting portions. The interval between the second projecting portions is the interval between the second projecting portions adjacent to each other. The interval between the first projecting portions is the interval between the first projecting portions adjacent to each other.

In FIG. 2, an interval W₁ between the first projecting portions 61 and an interval W₂ between the second projecting portions 62 are represented by respective double-pointed arrows. The interval between the first projecting portions adjacent to each other is determined as a distance between the centers of the figures forming the first projecting portions. Similarly, the interval between the second projecting portions adjacent to each other is determined as a distance between the centers of the figures forming the second projecting portions.

Preferably, the interval between the second projecting portions is 5 times to 50 times of the interval between the first projecting portions.

In addition, preferably, the interval between the second projecting portions is 1 mm to 5 mm. Preferably, the interval between the first projecting portions is 0.05 mm to 0.3 mm.

In the vapor chamber of the present invention, the shape of the housing is not particularly limited. Examples of the shape of the housing in top view include a polygon such as a triangle or a rectangle, a circle, an ellipse, and shapes formed by combining these shapes.

In the vapor chamber of the present invention, the first sheet and the second sheet that form the housing may overlap each other such that respective end portions thereof coincide with each other or such that the respective end portions thereof are misaligned.

In the vapor chamber of the present invention, the material forming the first sheet and the second sheet is not particularly limited as long as having characteristics suitable for the vapor chamber, such as a thermal conductivity, a strength, and flexibility. Preferably, the material forming the first sheet and the second sheet is a metal material. Examples of such a metal material include copper, nickel, aluminum, magnesium, titanium, iron, and alloys mainly composed of these metals. Particularly preferably, the material forming the first sheet and the second sheet is copper.

In the vapor chamber of the present invention, the material forming the first sheet and the material forming the second sheet may be different from each other. For example, use of a material having a high strength for the first sheet enables the stress applied to the housing to be dispersed. In addition, use of different materials for the respective sheets enables one of the sheets to have one function and the other of the sheets to have another function. Such functions are not particularly limited. Examples of such functions include a thermal conduction function and an electromagnetic shielding function.

In the vapor chamber of the present invention, the thickness of each of the first sheet and the second sheet is not particularly limited. However, when the first sheet and the second sheet are excessively thin, the strength of the housing is reduced, thus causing the housing to be easily deformed. Thus, the thickness of each of the first sheet and the second sheet is preferably 20 μm or more, more preferably 30 μm or more. On the other hand, when the first sheet and the second sheet are excessively thick, it is difficult to reduce the thickness of the entire vapor chamber. Thus, the thickness of each of the first sheet and the second sheet is preferably 150 μm or less, more preferably 100 μm or less, even more preferably 50 μm or less. The thickness of the first sheet and the thickness of the second sheet may be equal to each other or different from each other.

When the projecting portions are integral with the first sheet, the thickness of the first sheet is the thickness of a part thereof that is not in contact with the projecting portions. In addition, when the pillars are integral with the second sheet, the thickness of the second sheet is the thickness of a part thereof that is not in contact with the pillars.

In the vapor chamber of the present invention, the thickness of the first sheet may be uniform or ununiform. Similarly, the thickness of the second sheet may be uniform or ununiform. In addition, the part of the second sheet that is not in contact with the pillars may be recessed toward the inside of the housing.

In the vapor chamber of the present invention, the working fluid is not particularly limited as long as being capable of changing between a gas phase and a liquid phase in the environment in the housing. Usable examples of such a working fluid include water, alcohol, and alternative CFCs. The working fluid may be water.

In addition, the configuration of the vapor chamber of the present invention enables use of a compound, as a working fluid, having a lower boiling point than water. That is, it is possible to use a compound, as a working fluid, having a boiling point of lower than 100° C. Preferably, it is possible to use a compound, as a working fluid, having a boiling point of 50° C. or higher and 80° C. or lower. Usable specific examples of such a compound include alcohol and alternative CFCs.

In the vapor chamber of the present invention, the wick is not particularly limited as long as having a capillary structure capable of moving a working fluid by capillary force. The capillary structure of the wick may be a publicly known structure used in existing vapor chambers. Examples of such a capillary structure include fine structures including pores, grooves, or projections, such as a porous structure, a fiber structure, a groove structure, and a mesh structure.

In the vapor chamber of the present invention, the material for the wick is not particularly limited. Usable examples of such a material for the wick include a porous metal film formed by etching or metalworking, a mesh, a nonwoven fabric, a sintered body, and a porous body. Such a mesh serving as the material for the wick may be, for example, a metal mesh, a resin mesh, or one of these meshes subjected to surface coating and is preferably a copper mesh, a stainless steel (SUS) mesh, or a polyester mesh. Such a sintered body serving as the material for the wick may be, for example, a porous metal sintered body or a porous ceramic sintered body and is preferably a porous copper sintered body or a porous nickel sintered body. Such a porous body serving as the material for the wick may be, for example, a porous metal body, a porous ceramic body, or a porous resin body.

In addition, preferably, the wick is made of a material capable of being joined to the second projecting portions and the pillars by diffusion bonding. Preferably, the wick is made of a metal material such as copper, nickel, aluminum, magnesium, titanium, iron, an alloy mainly composed of these metals, or a porous sintered body. The wick may be made of the same material as that for the second projecting portions and the pillars.

In the vapor chamber of the present invention, preferably, the wick is provided in the housing so as to be continuous from an evaporation portion to a condensation portion. At least a part of the wick may be integral with the housing.

The vapor chamber of the present invention may have a cutout formed by cutting out a part of the wick. The vapor chamber has a cutout formed by cutting out a part of the wick, thus enabling an increase in the volume of the internal space (volume of a part of the internal space in which a gas-phase fluid can exist). As a result, it is possible to increase the amount of heat transported by the vapor chamber.

When a part of the wick is cut out, the vapor chamber easily expands in the vicinity of the cutout at a high internal pressure of the housing. Here, preferably, the pillars and the second projecting portions are provided on a part adjacent to the cutout. Provision of the pillars and the second projecting portions on a part adjacent to the cutout enables the vapor chamber to be inhibited from being expanded in the vicinity of the cutout.

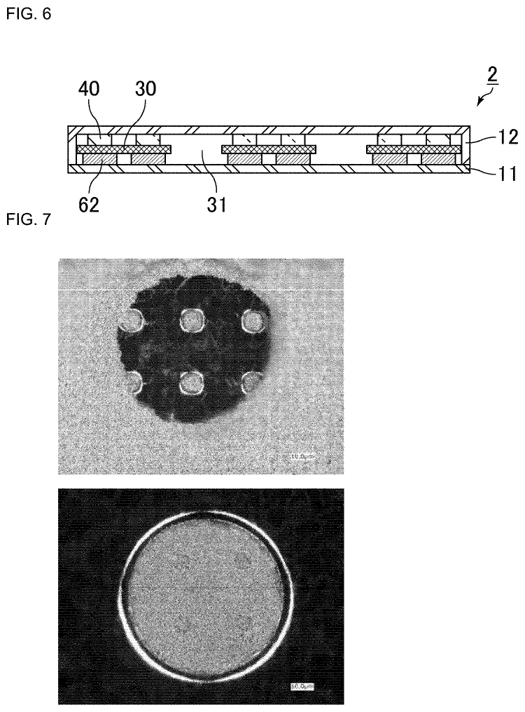

FIG. 5 is a schematic top sectional view of an example of another structure of the vapor chamber. FIG. 6 is a sectional view taken along line B-B in FIG. 5.

FIG. 5 is a top view when viewed from the side where the second sheet 12, which forms a vapor chamber 2, is located and illustrates the disposition of the pillars 40, the wick 30, and the projecting portions 60 (the first projecting portions 61 and the second projecting portions 62) so as to be seen through the second sheet 12.

Cutouts 31, each of which is formed by cutting out a part of the wick 30, exist in the vapor chamber 2 illustrated in FIGS. 5 and 6.

The pillars 40 and the second projecting portions 62 are provided on parts adjacent to the cutouts 31. The pillars 40, the first projecting portions 61, and the second projecting portions 62 are not provided in the cutouts 31.

The vapor chamber of the present invention is not limited to the above embodiment. Various applications and modifications can be made to, for example, the configuration and the manufacturing conditions of the vapor chamber within the scope of the present invention.

The vapor chamber of the present invention can be mounted in an electronic device to dissipate heat. Thus, the present invention also includes an electronic device including the vapor chamber of the present invention. Examples of the electronic device of the present invention include a smart phone, a tablet terminal, a notebook computer, a game device, and a wearable device. As described above, the vapor chamber of the present invention is capable of operating autonomously without external power and of diffusing heat two-dimensionally at high speed by using evaporation latent heat and condensation latent heat of a working fluid. Thus, the electronic device including the vapor chamber of the present invention is capable of effectively dissipating heat in a limited space in the electronic device.

The method for manufacturing the vapor chamber of the present invention is not particularly limited as long as enabling the above configuration to be obtained. For example, the first sheet on which the first projecting portions and the second projecting portions are disposed is prepared, the wick is disposed on the first projecting portions and the second projecting portions, and the first sheet and the second sheet on which the pillars are disposed are stacked. A working fluid is injected into the space between the first sheet and the second sheet, and the first sheet and the second sheet are joined to each other to obtain the vapor chamber.

The method for joining the first sheet and the second sheet is not particularly limited. Examples of such a method for joining the first sheet and the second sheet include laser welding, resistance welding, diffusion bonding, brazing, TIG welding (tungsten-inert gas welding), ultrasonic welding, and resin sealing. In particular, it is preferable to use laser welding, brazing, or diffusion bonding.

The first sheet and the second sheet are joined to each other with the sealing portion at the outer edges thereof, thus sealing the first sheet and the second sheet.

In addition, the wick is joined to the second projecting portions and the pillars with heat generated when the first sheet and the second sheet are joined to each other.

In addition, preferably, a part of the first sheet opposite to the second projecting portions and a part of the second sheet opposite to the pillars are pressed and heated so as to come into contact with a pressing jig and a heating jig for progressing diffusion bonding. In this manner, preferably, the wick is diffusion bonded to the second projecting portions and the pillars.

The first sheet and the second sheet are joined to each other so as to be aligned such that the positions of the second projecting portions and the respective positions of the pillars overlap each other. Alignment marks that are fiducial marks for alignment are provided on the first sheet and the second sheet, and these marks are then aligned to join the first sheet and the second sheet. Thus, the positions of the second projecting portions and the respective positions of the pillars overlap each other.

### EXAMPLES

Examples in which the vapor chamber of the present invention is more specifically disclosed will be described below. The present invention is not limited to only these examples.

### Example 1

A copper foil having a width of 60 mm, a length of 100 mm, and a thickness of 0.08 mm in plan view was prepared as a first sheet. The first sheet was etched with sodium persulfate. Thus, first projecting portions having a quadrangular prism shape and second projecting portions having a cylindrical shape were formed on an inner wall surface of the first sheet.

The area of a section of the first projecting portion perpendicular to the height direction was 0.01 mm². In addition, the interval between the first projecting portions adjacent to each other was 0.1 mm.

The area of a section of the second projecting portion perpendicular to the height direction was 0.3 mm². In addition, the interval between the second projecting portions adjacent to each other was 3 mm.

The height of the first projecting portion from the inner wall surface of the first sheet and the height of the second projecting portion from the inner wall surface of the first sheet were equal to each other.

Separately, a copper foil having a width of 60 mm, a length of 100 mm, and a thickness of 0.2 mm in plan view was prepared as a second sheet. The second sheet was etched with sodium persulfate. Thus, pillars having a cylindrical shape were formed on an inner wall surface thereof.

The area of a section of the pillar perpendicular to the height direction was 0.3 mm². In addition, the interval between the pillars adjacent to each other was 3 mm.

A wick was disposed so as to be held between the first sheet on which the projecting portions were formed and the second sheet on which the pillars were formed. An outer edge portion of the first sheet and an outer edge portion of the second sheet were laser welded to each other and thus sealed. A porous metal body was used as the wick.

When the first sheet and the second sheet were stacked, the first sheet and the second sheet were aligned such that the positions of the second projecting portions and the respective positions of the pillars overlapped each other, and specifically, such that 90% or more of the area of the pillar overlapped the second projecting portion in plan view in the direction in which the first sheet and the second sheet faced each other.

After the welding, methanol, as a working fluid, having a boiling point of 65° C. was injected into the space between the first sheet and the second sheet through a pipe. Through the above process, a vapor chamber in Example 1 was obtained.

### Examples 2 to 4

Alignment when the first sheet and the second sheet were stacked was adjusted to vary, as illustrated in Table 1, the percentage of the area of the pillar overlapping the second projecting portion in plan view in the direction in which the first sheet and the second sheet faced each other. Vapor chambers were obtained such that the other configurations were similar to those of Example 1.

### Comparative Example 1

The pattern used when the first sheet was etched was changed to form, as the projecting portions, only projecting portions each having the same size as the first projecting portion in Example 1. That is, the second projecting portions were not provided.

When the first sheet and the second sheet were stacked, deliberate alignment between the first sheet and the second sheet was not particularly performed, and the pillars overlapped some first projecting portions in plan view in the direction in which the first sheet and the second sheet faced each other. A vapor chamber was obtained such that the other configurations were similar to those of Example 1.

The vapor chambers obtained in the examples and comparative example were placed in a constant temperature oven, and external appearances of the vapor chambers in the constant temperature oven at a heating rate of 5° C./min were observed. Temperatures of a heat source when the vapor chambers started to expand were recorded as expansion start temperatures. It can be said that a vapor chamber whose expansion start temperature is higher is less likely to expand.

TABLE 1

| | Percentage of Pillar | Expansion Start |
|---|---|---|
| | Overlapping Second | Temperature |
| | Projecting Portion (%) | (° C.) |
| Example 1 | 90 | 140 |
| Example 2 | 75 | 130 |
| Example 3 | 60 | 100 |
| Example 4 | 30 | 90 |
| Comparative | No Second | 70 |
| Example 1 | Projecting Portion | |

It is clear from Table 1 that the second projecting portions are provided on the first sheet, the pillars are provided on the second sheet, and the pillars and the second projecting portions are disposed such that the positions of the pillars and the respective positions of the second projecting portions overlap each other, thus enabling the vapor chamber to be inhibited from being expanded.

In addition, it is clear that an increase in the area of the pillar overlapping the second projecting portion enables such expansion to be inhibited more effectively.

External appearances of the projecting portions, the wick, and the pillars of the expanded vapor chamber were observed.

FIG. 7 includes photographs each illustrating an external appearance of a stripped plane of Comparative Example 1. The upper photograph is a photograph in which the stripped plane is viewed toward the projecting portions and in which the projecting portions that have existed below the stripped wick appear. The lower photograph is a photograph in which the stripped plane is viewed toward the pillars and in which the stripped wick and the pillar behind the wick appear.

In Comparative Example 1 in which the second projecting portions were not provided, a part of the wick was adhered to form a shape along a sectional shape of the pillar, and a fracture mode in which the projecting portions and the wick were stripped from each other appeared.

This means that a part closer to the second sheet easily deforms because the interval between the pillars adjacent to each other is larger than the interval between the projecting portions adjacent to each other. In addition, this means that the part of the wick joined to the pillar is stripped from the projecting portions because the area of the projecting portion is smaller than that of the pillar.

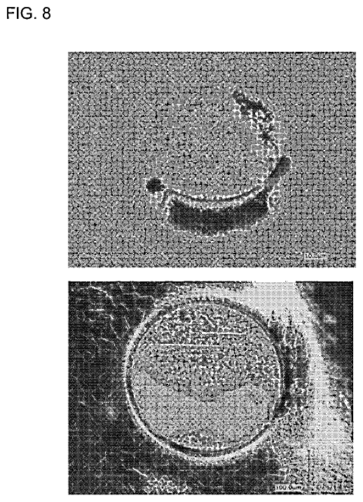

FIG. 8 includes photographs each illustrating an external appearance of a stripped plane of Example 1. The upper photograph is a photograph in which the stripped plane is viewed toward the projecting portions and in which the second projecting portion and the wick appear. The lower photograph is a photograph in which the stripped plane is viewed toward the pillars and in which the stripped wick and the pillar appear.

On the other hand, in each of Examples in which the second projecting portions were provided, most of the wick was adhered to the second projecting portions, and a fracture mode in which the wick and the pillars were stripped from each other appeared.

The second projecting portions each have a large area and are thus firmly joined to the wick. This means that the wick is less likely to be stripped from the projecting portions and that such a fracture mode in Comparative Example 1 is less likely to appear.

In addition, a fracture mode in which a part of the wick was adhered to the pillar and was stripped appeared in a part where the second projecting portion and the pillar did not overlap each other. This means that the wick is pulled by the pillar in a part where the second projecting portion and the pillar do not overlap each other, and the fracture mode in which a part of the wick is adhered to the pillar and is stripped thus appears therein.

The vapor chamber of the present invention can be used for various purposes in the field of, for example, portable information terminals. For example, the vapor chamber of the present invention can be used to reduce the temperature of a heat source such as a CPU and to extend the operating time of an electronic device and can be used for smart phones, tablet terminals, notebook computers, and the like.

### REFERENCE SIGNS LIST

1, 2 vapor chamber
10 housing
11 first sheet
11a inner wall surface of first sheet
12 second sheet
12a inner wall surface of second sheet
13 internal space
20 working fluid
30 wick
31 cutout
40 pillar
50 sealing portion
60 projecting portion
61 first projecting portion
62 second projecting portion
70 heat generation member

1. A vapor chamber comprising:
a housing having a first sheet and a second sheet that have respective outer edges joined to each other such that the first sheet and the second sheet face each other and define an internal space between an inner wall surface of the first sheet and an inner wall surface of the second sheet;
a working fluid enclosed in the internal space of the housing;
a plurality of first projecting portions on the inner wall surface of the first sheet so as to be spaced from each other;
a plurality of second projecting portions on the inner wall surface of the first sheet so as to be spaced from each other, an area of a section of each of the plurality of second projecting portions perpendicular to a height direction thereof being larger than an area of a section of each of the plurality of first projecting portions perpendicular to the height direction thereof;
a plurality of pillars on the inner wall surface of the second sheet so as to be spaced from each other and at respective positions overlapping the plurality of second projecting portions in a plan view in a direction in which the first sheet and the second sheet face each other; and
a wick between and joined to the plurality of pillars and the plurality of second projecting portions.

2. The vapor chamber according to claim 1, wherein 75% or more of an area of each of the plurality of pillars overlaps a corresponding one of the plurality of second projecting portions in the plan view in the direction in which the first sheet and the second sheet face each other.

3. The vapor chamber according to claim 1, wherein the area of the section of each of the plurality of second projecting portions perpendicular to the height direction thereof is larger than an area of a section of each of the plurality of pillars perpendicular to the height direction thereof.

4. The vapor chamber according to claim 1, wherein a ratio of the area of the section of each of the plurality of second projecting portions perpendicular to the height direction thereof to an area of a section of each of the plurality of pillars perpendicular to the height direction thereof is 100% to 130%.

5. The vapor chamber according to claim 1, wherein the area of the section of each of the plurality of second projecting portions perpendicular to the height direction thereof is 0.2 mm² to 4 mm².

6. The vapor chamber according to claim 5, wherein an area of a section of each of the plurality of pillars perpendicular to the height direction thereof is 0.15 mm² to 4 mm².

7. The vapor chamber according to claim 1, wherein an area of a section of each of the plurality of pillars perpendicular to the height direction thereof is 0.15 mm² to 4 mm².

8. The vapor chamber according to claim 1, wherein a first interval between adjacent second projecting portions of the plurality of second projecting portions is larger than a second interval between adjacent first projecting portions of the plurality of first projecting portions.

9. The vapor chamber according to claim 1, wherein a first interval between adjacent second projecting portions of the plurality of second projecting portions is 5 times to 50 times of a second interval between adjacent first projecting portions of the plurality of first projecting portions.

10. The vapor chamber according to claim 1, wherein an interval between adjacent second projecting portions of the plurality of second projecting portions is 1 mm to 5 mm.

11. The vapor chamber according to claim 1, wherein an interval between adjacent first projecting portions of the plurality of first projecting portions is 0.05 mm to 0.3 mm.

12. The vapor chamber according to claim 1, wherein the area of the section of each of the plurality of second projecting portions perpendicular to the height direction thereof is 20 times to 200 times of the area of the section of each of the plurality of first projecting portions perpendicular to the height direction thereof.

13. The vapor chamber according to claim 1, wherein the area of the section of each of the plurality of first projecting portions perpendicular to the height direction thereof is 0.0025 mm² to 0.04 mm².

14. The vapor chamber according to claim 1, wherein a part of the wick includes at least one cutout in the plan view in the direction in which the first sheet and the second sheet face each other.

15. The vapor chamber according to claim 14, wherein at least one of the plurality of pillars and at least one of the plurality of second projecting portions are adjacent to the at least one cutout.

16. The vapor chamber according to claim 15, wherein the plurality of pillars, the plurality of first projecting portions, and the plurality of second projecting portions are not provided in the at least one cutout.

17. The vapor chamber according to claim 1, wherein a first pattern in which the plurality of pillars are disposed is the same as a second pattern in which the plurality of second projecting portions are disposed.

18. An electronic device comprising the vapor chamber according to claim 1.
